(19) United States
(12) Patent Application Publication
(10) Pub. No.: US 2013/0235001 A1
(43) Pub. Date: Sep. 12, 2013

(54) PIEZOELECTRIC RESONATOR WITH AIRGAP

(71) Applicants: Changhan Hobie YUN, San Diego, CA (US); Je-Hsiung Jeffrey LAN, San Diego, CA (US); Chengjie ZUO, Santee, CA (US); Chi Shun LO, San Diego, CA (US); Jonghae KIM, San Diego, CA (US)

(72) Inventors: Changhan Hobie YUN, San Diego, CA (US); Je-Hsiung Jeffrey LAN, San Diego, CA (US); Chengjie ZUO, Santee, CA (US); Chi Shun LO, San Diego, CA (US); Jonghae KIM, San Diego, CA (US)

(73) Assignee: QUALCOMM MEMS TECHNOLOGIES, INC., San Diego, CA (US)

(21) Appl. No.: 13/413,613

(22) Filed: Mar. 6, 2012

(51) Int. Cl. G09G 3/00; G06F 3/038; H01L 41/22; H01L 41/047

(52) U.S. Cl. 345/204; 310/365; 345/31; 29/25.35

(57) ABSTRACT

This disclosure provides implementations of electromechanical systems (EMS) piezoelectric resonator structures, transformers, devices, apparatus, systems, and related processes. In one aspect, a piezoelectric resonator structure includes a first conductive electrode layer, a second conductive electrode layer, and a piezoelectric layer arranged between the first and second conductive layers. In some implementations, the surface of the piezoelectric layer adjacent to the first conductive layer is separated from the first conductive layer by a first gap, and the surface of the piezoelectric layer adjacent to the second conductive layer is separated from the second conductive layer by a second gap. In some implementations, the resonator structure further includes an encapsulation layer arranged over the second conductive layer and providing physical support to the second conductive layer.

### TECHNICAL FIELD

This disclosure relates generally to electromechanical systems (EMS), and more specifically to piezoelectric EMS resonators in which electrodes are disposed in close proximity to—but separated from—a piezoelectric material.

### DESCRIPTION OF THE RELATED TECHNOLOGY

Electromechanical systems (EMS) include devices having electrical and mechanical elements, transducers such as actuators and sensors, optical components (including mirrors), and electronics. EMS can be manufactured at a variety of scales including, but not limited to, microscales and nanoscales. For example, microelectromechanical systems (MEMS) devices can include structures having sizes ranging from about one micron to hundreds of microns or more. Nanoelectromechanical systems (NEMS) devices can include structures having sizes smaller than one micron including, for example, sizes smaller than several hundred nanometers. Electromechanical elements may be created using deposition, etching, lithography, or other micromachining processes that etch away parts of substrates or deposited material layers, or that add layers to form electrical, mechanical, and electromechanical devices.

One type of EMS device is called an interferometric modulator (IMOD). As used herein, the term IMOD or interferometric light modulator refers to a device that selectively absorbs or reflects light using the principles of optical interference. In some implementations, an IMOD may include a pair of conductive plates, one or both of which may be transparent or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the IMOD. IMOD devices have a wide range of applications, and are anticipated to be used in improving existing products and creating new products, especially those with display capabilities.

Various electronic circuit components can be implemented at the EMS level, including resonators. Some conventional resonator designs have less than desirable attributes, such as poor electromechanical coupling (kₜ²), high resistance, or low quality (Q) factor. These attributes can be inherent with certain conventional piezoelectric resonator structure designs, in which upper and lower electrodes are in direct contact with a piezoelectric layer arranged between the upper and lower electrodes. To improve the device characteristics, for example, parallel attachment methods can be used in some piezoelectric resonators. For example, a resonator can be constructed with one or both conductive layers having multiple fingers (electrodes) attached to a piezoelectric material and connected with other such resonator structures as part of a multi-resonator array. However, in some implementations, trade-offs between design and performance may exist.

For example, to achieve greater kₜ² and higher frequency operation, it may be desirable to scale down the dimensions of the piezoelectric material and conductive layers. However, traditionally, the electrodes cannot scale down at the rate of the scaling down of the piezoelectric layer because further scaling results in excessive electrode and interconnect resistance and energy loss. Conversely, by increasing the thickness of the electrodes, the electrode resistance and overall device impedance can be reduced. However, when the electrode thickness is increased, the electrodes dissipate more energy in the form of, for example, metal material and electrode-to-piezoelectric material interface losses, resulting in a lower Q factor. More generally, as the thickness of the electrodes is increased, the piezoelectric motion is inhibited by so-called “mass loading,” resulting in the lower Q factor and limiting the scaling of the devices towards higher frequency operation. In some other designs, the electrodes can be made thinner but are generally wider, which can then require wider supports for the electrodes, which results in more energy loss and a reduced Q factor.

### SUMMARY

The structures, devices, apparatus, systems, and processes of the disclosure each have several innovative aspects, no single one of which is solely responsible for the desirable attributes disclosed herein.

Disclosed are example implementations of piezoelectric EMS resonators, transducers, transformers, devices, apparatus, systems, and related fabrication processes.

According to one innovative aspect of the subject matter described in this disclosure, a piezoelectric resonator structure includes a first conductive layer including one or more first electrodes; a second conductive layer including one or more second electrodes; a piezoelectric layer including one or more layers of piezoelectric material, the piezoelectric layer being arranged between the first conductive layer and the second conductive layer, at least a portion of the surface of the piezoelectric layer adjacent to the first conductive layer being separated from the first conductive layer by a first gap, at least a portion of the surface of the piezoelectric layer adjacent to the second conductive layer being separated from the second conductive layer by a second gap; and an encapsulation layer arranged over the second conductive layer, the encapsulation layer providing physical support to the second conductive layer. The first and second conductive layers are configured such that the piezoelectric layer is capable of displacement responsive to one or more electrical signals provided to one or more of the first or second electrodes.

In some implementations, the piezoelectric resonator structure achieves a motional resistance less than approximately 1Ω. In some implementations, one or both of the first and second conductive layers each has a thickness in the range of approximately 4000 Å to approximately 40000 Å. In some implementations, the piezoelectric layer has a thickness in the range of approximately 4000 Å to 40000 Å. In some implementations, the first gap has a thickness in the range of approximately 10 Å to approximately 1000 Å. In some implementations, the second gap also has a thickness in the range of approximately 10 Å to approximately 1000 Å.

According to another innovative aspect of the subject matter described in this disclosure, a method includes forming a first conductive layer over a substrate, the first conductive layer including one or more first electrodes; forming a first sacrificial layer over the first conductive layer; forming a piezoelectric layer over the first sacrificial layer; forming a second sacrificial layer over the piezoelectric layer; forming a second conductive layer over the second sacrificial layer, the second conductive layer including one or more second electrodes; forming an encapsulation layer over the second conductive layer; and releasing or removing the first and second sacrificial layers. When the first and second sacrificial layers are removed, the method results in a first gap between the first conductive layer and the piezoelectric layer, and a second gap between the second conductive layer and the piezoelectric layer. The encapsulation layer provides physical support to the second conductive layer.

In some implementations, one or both of the first and second sacrificial layers are formed of molybdenum (Mo) or an amorphous silicon (a-Si) structure. In some implementations, the resultant piezoelectric resonator structure achieves a motional resistance less than approximately 1Ω. In some implementations, one or both of the first and second conductive layers each has a thickness in the range of approximately 4000 Å to approximately 40000 Å. In some implementations, the piezoelectric layer has a thickness in the range of approximately 4000 Å to 40000 Å. In some implementations, the first gap has a thickness in the range of approximately 10 Å to approximately 1000 Å. In some implementations, the second gap also has a thickness in the range of approximately 10 Å to approximately 1000 Å.

According to another innovative aspect of the subject matter described in this disclosure, a piezoelectric resonator structure includes first conductive means including one or more first electrodes; second conductive means including one or more second electrodes; piezoelectric means including one or more layers of piezoelectric material, the piezoelectric means being arranged between the first conductive means and the second conductive means, at least a portion of the surface of the piezoelectric means adjacent to the first conductive means being separated from the first conductive means by a first gap, at least a portion of the surface of the piezoelectric means adjacent to the second conductive means being separated from the second conductive means by a second gap; and support means arranged over the second conductive means, the support means providing physical support to the second conductive means. The first and second conductive means are configured such that the piezoelectric means are capable of displacement responsive to one or more electrical signals provided to one or more of the first or second electrodes.

In some implementations, the piezoelectric resonator structure achieves a motional resistance less than approximately 1Ω. In some implementations, one or both of the first and second conductive layers each has a thickness in the range of approximately 4000 Å to approximately 40000 Å. In some implementations, the piezoelectric layer has a thickness in the range of approximately 4000 Å to 40000 Å. In some implementations, the first gap has a thickness in the range of approximately 10 Å to approximately 1000 Å. In some implementations, the second gap also has a thickness in the range of approximately 10 Å to approximately 1000 Å.

Details of one or more implementations of the subject matter described in this specification are set forth in the accompanying drawings and the description below. Although the examples provided in this disclosure are primarily described in terms of EMS and MEMS-based displays, the concepts provided herein may apply to other types of displays, such as liquid crystal displays, organic light-emitting diode (“OLED”) displays and field emission displays. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows a cross-sectional side view of an example piezoelectric resonator structure having gaps between electrode layers and a piezoelectric material layer.

FIG. 2 shows a hidden top view of an example piezoelectric resonator structure, such as that depicted in FIG. 1.

FIG. 3 shows a cross-sectional side view of an example implementation of a piezoelectric resonator structure that includes one or more first electrodes, one or more second electrodes arranged opposite the first electrodes, one or more third electrodes, and one or more fourth electrodes arranged opposite the third electrodes.

FIG. 4 shows a cross-sectional side view of an example implementation of a piezoelectric resonator structure that includes one or more first electrodes, one or more second electrodes arranged opposite the first electrodes, one or more third electrodes, one or more fourth electrodes arranged opposite the third electrodes, one or more fifth electrodes, and one or more sixth electrodes arranged opposite the fifth electrodes.

FIG. 5 shows a flow diagram depicting an example process for forming an example piezoelectric resonator structure.

FIGS. 6A-6G show cross-sectional side views during various stages of the process depicted in FIG. 5.

FIGS. 7A-7G show top views during various stages of the process depicted in FIG. 5.

FIG. 8 shows another cross-sectional side view of the example piezoelectric resonator structure depicted in FIG. 1.

FIG. 9 shows a flow diagram depicting another example process for forming a piezoelectric resonator structure.

FIGS. 10A-10H show cross-sectional side views during various stages of the example process depicted in FIG. 9.

FIG. 11 shows a flow diagram depicting another example process for forming a piezoelectric resonator structure.

FIGS. 12A-12G show cross-sectional side views during various stages of the example process depicted in FIG. 11.

FIG. 13 shows a flow diagram depicting another example process for forming a piezoelectric resonator structure.

FIGS. 14A-14I show cross-sectional side views during various stages of the example process depicted in FIG. 13.

FIG. 15A shows an isometric view depicting two adjacent example pixels in a series of pixels of an example IMOD display device.

FIG. 15B shows an example system block diagram depicting an example electronic device incorporating an IMOD display.

FIGS. 16A and 16B show examples of system block diagrams depicting an example display device that includes a plurality of IMODs.

Like reference numbers and designations in the various drawings indicate like elements.

### DETAILED DESCRIPTION

The following detailed description is directed to certain implementations for the purposes of describing the innovative aspects. However, the teachings herein can be applied and implemented in a multitude of different ways.

The disclosed implementations include examples of structures and configurations of EMS resonator devices, including piezoelectric EMS resonator transducers. Related apparatus, systems, and fabrication processes and techniques are also disclosed. In the disclosed implementations of example piezoelectric EMS resonators (hereinafter “piezoelectric resonators”), electrodes are arranged in close proximity to—but separated from—a piezoelectric material. For instance, the electrodes can be located adjacent to the same surface or adjacent to opposite surfaces of a layer of the piezoelectric material.

The resonator structures described herein include structures with separations or “gaps” between the piezoelectric layer and one or both of the lower and upper conductive layers, including the electrodes in these conductive layers. In some implementations, using thin-film encapsulation technology, an encapsulation or “shell” layer is deposited on or over the upper conductive layer. In this way, the encapsulation layer is attached to the otherwise floating or suspended electrodes of the upper conductive layer to support and hold the electrodes of the upper conductive layer in position in close proximity to, but separated from, the piezoelectric layer.

In some implementations, one or both of the gaps can be evacuated of air or filled with other gas. In some implementations, the thicknesses of the electrodes in one or both of the upper and lower conductive layers are maximized to lower the overall impedance of the device, subject to one or more other constraints such as device size or frequency or power constraints. For example, the thickness of each electrode in one or more of the upper and lower conductive layers is on the order of one or several micrometers (μm). In some implementations, the piezoelectric resonator structure or device achieves a motional impedance or resistance of less than approximately 1 Ohm (Ω). In some implementations, the thicknesses of the gaps (the extent of the separation) between the piezoelectric layer and one or both of the upper and lower conductive layers are minimized to maximize the use of the electric field generated between the upper and lower electrodes to achieve the largest possible piezoelectric effect—the greatest strain or displacement—subject to one or more other constraints. For example, the upper gap can be made at least suitably thick enough such that any upward bending (sometimes referred to as “tenting”) of the piezoelectric layer due to stress in the piezoelectric layer (also referred to as the “resonator beam”) does not result in the piezoelectric layer contacting the upper conductive layer. However, with sufficient process controls, tenting can be prevented enabling the minimization of the gaps.

The aforementioned piezoelectric resonator structure arrangement can decouple various performance characteristics from the dimensions, particularly the thicknesses, of the conductive layers or piezoelectric layers. In particular, by separating the conductive electrode layers from the piezoelectric layer, a higher Q factor can be achieved while also maintaining high kₜ² and allowing for high frequency operation (such as greater than 1 GHz). These parallel achievements are possible, at least in part, because the separation between the electrodes and the piezoelectric material allows for thicker electrodes—and thus lower electrode resistance or motional impedance—while also allowing for a large piezoelectric effect, maintaining high electromechanical coupling kₜ² and increasing the Q factor.

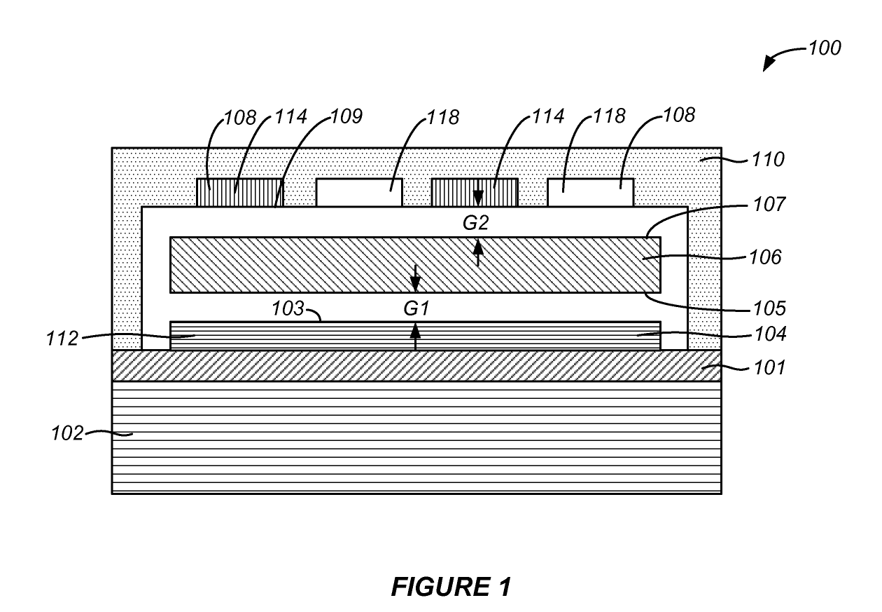

FIG. 1 shows a cross-sectional side view of an example piezoelectric resonator structure 100 having gaps between electrode layers and a piezoelectric material layer. The piezoelectric resonator structure 100 includes a substrate 102, a first (lower) conductive layer 104 arranged over the substrate, a piezoelectric layer 106 arranged over the first conductive layer 104, a second (upper) conductive layer 108 arranged over the piezoelectric layer 106, and an encapsulation layer 110 arranged over the second conductive layer 108. In some implementations, the first conductive layer 104 includes a single first electrode 112. In other implementations, the first conductive layer 104 includes a first set of two or more first electrodes 112. In some implementations, the second conductive layer 108 includes a single second electrode 114 arranged opposite the one or more first electrodes 112. In other implementations, the second conductive layer 108 includes a second set of two or more second electrodes 114 arranged opposite the one or more first electrodes 112.

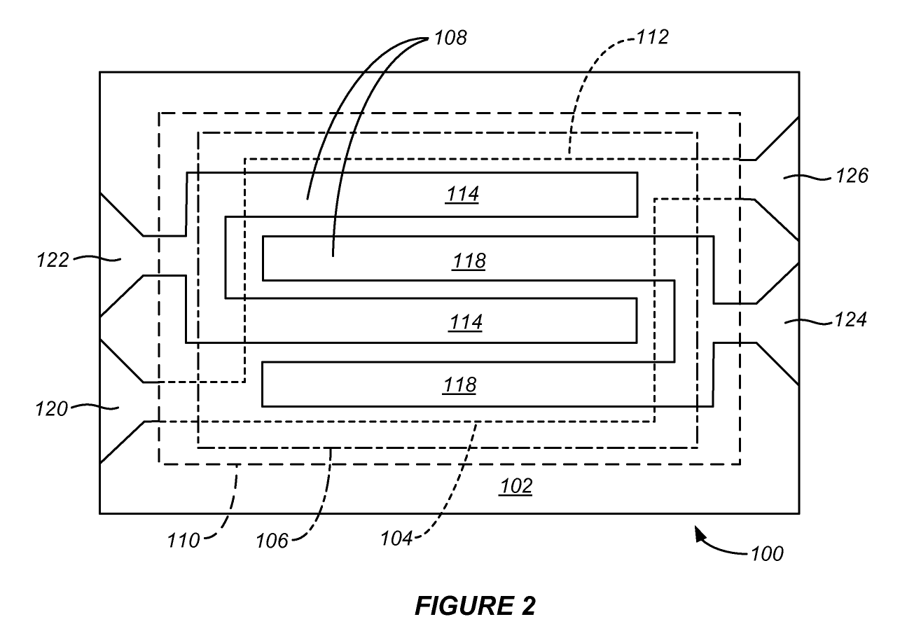

FIG. 2 shows a hidden top view of an example piezoelectric resonator structure, such as that depicted in FIG. 1. In FIG. 2, the piezoelectric resonator structure 100 includes a single first electrode 112 and two second electrodes 114. The periphery of the encapsulation layer 110 is also shown with dotted lines.

In some implementations, substrate 102 can be formed of an insulating or dielectric material. In some particular implementations, the disclosed piezoelectric resonator structure 100 can be fabricated on a low-cost, high-performance, large-area insulating substrate 102. In some implementations, the substrate 102 on which the disclosed piezoelectric resonator structure 100 is formed can be made of display-grade glass (alkaline earth boro-aluminosilicate) or soda lime glass. Other suitable insulating materials from which the substrate 102 can be made include silicate glasses, such as alkaline earth aluminosilicate, borosilicate, modified borosilicate, and others. Also, ceramic materials such as aluminum oxide (AlOx), yttrium oxide (Y₂O₃), boron nitride (BN), silicon carbide (SiC), aluminum nitride (AlN), and gallium nitride (GaNx) can be used as the insulating substrate material. In some other implementations, the insulating substrate 102 is formed of high-resistivity silicon. In some implementations, silicon on insulator (SOI) substrates, gallium arsenide (GaAs) substrates, indium phosphide (InP) substrates, and plastic (polyethylene naphthalate or polyethylene terephthalate) substrates, e.g., associated with flexible electronics, also can be used. The substrate 102 can be in conventional Integrated Circuit (IC) wafer form, e.g., 4-inch, 6-inch, 8-inch, 12-inch, or in large-area panel form. For example, flat panel display substrates with dimensions such as 370 mm×470 mm, 920 mm×730 mm, and 2850 mm×3050 mm, can be used.

Additionally, as FIG. 1 shows, in some example implementations a thin barrier oxide layer 101 can be formed over the substrate 102 before the first conductive layer 104 is deposited. In some implementations, the first conductive layer 104 can be formed of a highly conductive metal material or alloy such as, for example, nickel (Ni). In some example implementations, the first conductive layer 104 is relatively thick. For example, in some applications, a thickness in the range of approximately 4000 Angstroms (Å) to approximately 40000 Å can be suitable to achieve the aforementioned impedance goals or other goals. However, thinner or thicker thicknesses may be appropriate or suitable in other implementations or applications. In some implementations, piezoelectric layer 106 is formed of a single piezoelectric material layer such as, for example, an AlN thin film. Although suitable thicknesses may vary, in some implementations the piezoelectric layer 106 has a thickness in the range of approximately 4000 Å to approximately 40000 Å. However, thinner or thicker thicknesses may be appropriate or suitable in other implementations or applications. In some implementations, the second conductive layer 108 can be formed of a highly conductive metal material or alloy such as, for example, Ni. In some example implementations, the second conductive layer 108 is also relatively thick—for example, in some applications, also in the range of approximately 4000 Å to approximately 40000 Å. Again, thinner or thicker thicknesses may be appropriate or suitable in other implementations or applications. Generally, it may be desirable to maximize the thickness of the first and second conductive layers 104 and 108, respectively, in order to reduce the overall resistance.

In some implementations, the encapsulation or shell layer 110 can be formed of a planarization material such as, for example, silicon (Si), silicon dioxide (SiO₂) or silicon oxynitride (SiON). In some other implementations, the encapsulation layer 110 can be formed of a metal. In some such implementations, the encapsulation layer 110 can have a thickness of approximately 3 μm but thinner or thicker thicknesses may be appropriate or suitable in other implementations or applications. In some implementations, the encapsulation layer 110 can be formed using one or more thin-film encapsulation techniques.

As FIG. 1 shows, the piezoelectric resonator structure 100 can include a first gap G1 that separates the top surface 103 of the first conductive layer 104 from the adjacent bottom surface 105 of the piezoelectric layer 106. Similarly, the piezoelectric resonator structure 100 can include a second gap G2 that separates the top surface 107 of the piezoelectric layer 106 from the adjacent bottom surface 109 of the second conductive layer 108.

In some implementations, one or both of the gaps G1 and G2 are evacuated of air or filled with other gas. In some implementations, the thicknesses of one or both of the gaps G1 and G2 between the piezoelectric layer 106 and the first and second conductive layers 104 and 108, respectively, are minimized to maximize the use of the electric field generated between the electrodes 112 and 114 of the first and second conductive layers 104 and 108, respectively, to achieve the largest possible piezoelectric effect. That is, to achieve the greatest strain or displacement in or of the piezoelectric layer 106—subject to one or more other constraints. For example, in some implementations the thickness of the second (upper) gap G2 can be in the range of approximately 10 Å to approximately 1000 Å. However, thinner or thicker thicknesses may be appropriate or suitable in other implementations or applications. In general, it may be desirable to minimize the gap, but in order to account for possible tenting during operation, a greater G2 thickness may be desirable. However, as described above, tenting can be prevented by using sufficient process controls. In some implementations, a thickness of the first (lower) gap G1 also can be in the range of approximately 10 Å to approximately 1000 Å. Although, again, thinner or thicker thicknesses may be appropriate or suitable in other implementations or applications.

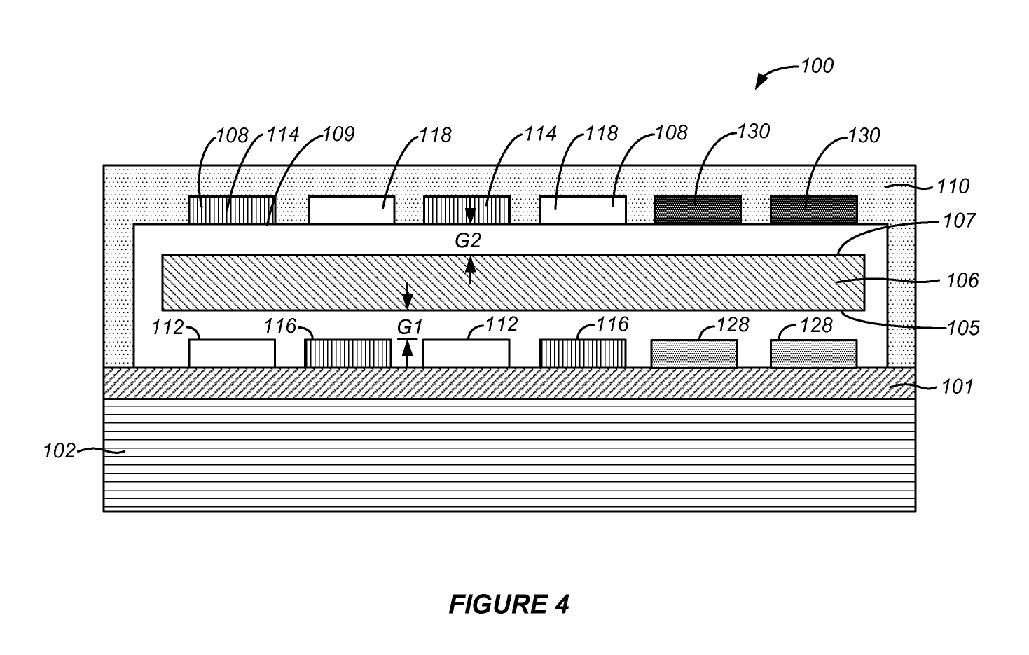

As FIGS. 1 and 2 show, the encapsulation layer 110 supports the upper conductive layer 108 thereby enabling the piezoelectric layer 106 to be physically-decoupled from the second electrodes 114 and the fourth electrodes 118 any other electrodes (such as sixth electrodes 130 included in the upper conductive layer 108 in the implementation depicted in FIG. 4) or traces in the second conductive layer 108 (While reference numerals 108 may point to the same elements also referenced as 114 or 118 in FIGS. 1 and 2, this is for didactic purposes as 108 points to the upper conductive layer while 114 and 118 point to second electrodes or fourth electrodes integrally formed within or of the upper conductive layer 108 when forming and patterning the upper conductive layer 108. Similarly, while reference numerals 104 may point to the same elements also referenced as 112 or 116 in FIGS. 1 and 2, this is for didactic purposes as 104 points to the lower conductive layer while 112 and 116 point to first electrodes or third electrodes integrally formed within or of the lower conductive layer 104 when forming and patterning the lower conductive layer 104).

The piezoelectric resonator structure 100 also can include a first port 120 capable of receiving a first input signal, such as a varying input signal. In other implementations, first port 120 can be coupled to a ground. In some implementations, the first electrodes 112 are coupled to the first port 120. The piezoelectric resonator structure 100 also can include a second port 122 that can be coupled to a second input signal, such as a varying input signal. In some other implementations, the second port 122 can be coupled to a ground. In some implementations, the second electrodes 114 are coupled to the second port 122. In other implementations, either of the first port 120 or the second port 122 can be coupled to an output node or load and capable of outputting an output signal.

By way of reference, an electric field applied via the first or second input signals between first electrodes 112 and second electrodes 114 is transduced into a mechanical strain in the piezoelectric material layer 106. For example, a time-varying electrical input signal can be provided to the second port 122 and the second electrodes 114 while the first port 120 and first electrodes 112 are coupled to ground (in other implementations the first port 120 and first electrodes 112 can be coupled to a first time-varying input signal having a polarity opposite that of a second time-varying input signal applied to the second port 122 and the second electrodes 114). The time-varying electrical signal is transduced to a corresponding time-varying mechanical motion in the piezoelectric layer 106 due to the piezoelectric effect. The frequencies of the input electrical signal(s) that produce the greatest substantial amplifications of the mechanical displacement in the piezoelectric material are generally referred to as resonant frequencies.

In some implementations, as FIG. 2 shows, the second conductive layer 108 can include one or more other electrodes 118 that can be coupled to an output port 124, which can be coupled to a load and capable of outputting an output signal. In such an implementation, the output signal may be a time-varying electrical signal resulting from the reverse piezoelectric effect—the transduction of mechanical strain in the piezoelectric layer 106 (caused from the time-varying input signal) to electrical energy.

In some implementations, the first port 120 and the second port 122, or the signals routed through them, can be reversed. In some implementations, the second port 122 and the output port 124, or the signals routed through them, can be reversed. Generally, the switching of the ports, or the signals traversing them, can be exchanged or reversed in many of the implementations described or disclosed herein.

Some implementations described herein are based on a contour mode resonator (CMR) configuration. In such implementations, the resonant frequency of a CMR can be substantially controlled by engineering the lateral (e.g., length and width) dimensions of the piezoelectric material layer 106 and the electrodes 112 and 114, as well as engineering the periodicity of the electrodes 112 or 114, for example, and the thickness of the piezoelectric layer 106. One benefit of such a construction is that multi-frequency RF filters, clock oscillators, transformers, transducers or other devices, each including one or more CMRs depending on the desired implementation, can be fabricated on the same substrate. For example, this may be advantageous in terms of cost and size by enabling compact, multi-band filter solutions for RF front-end applications on a single chip. In some examples, by co-fabricating multiple CMRs with different finger widths, as described in greater detail below, multiple frequencies can be addressed on the same die. In some examples, arrays of CMRs with different frequencies spanning a range from MHz to GHz can be fabricated on the same substrate.

In other implementations, the piezoelectric resonator structures described herein can be configured in a film bulk acoustic resonator (FBAR) or thin-film bulk acoustic resonator (TFBAR) configuration.

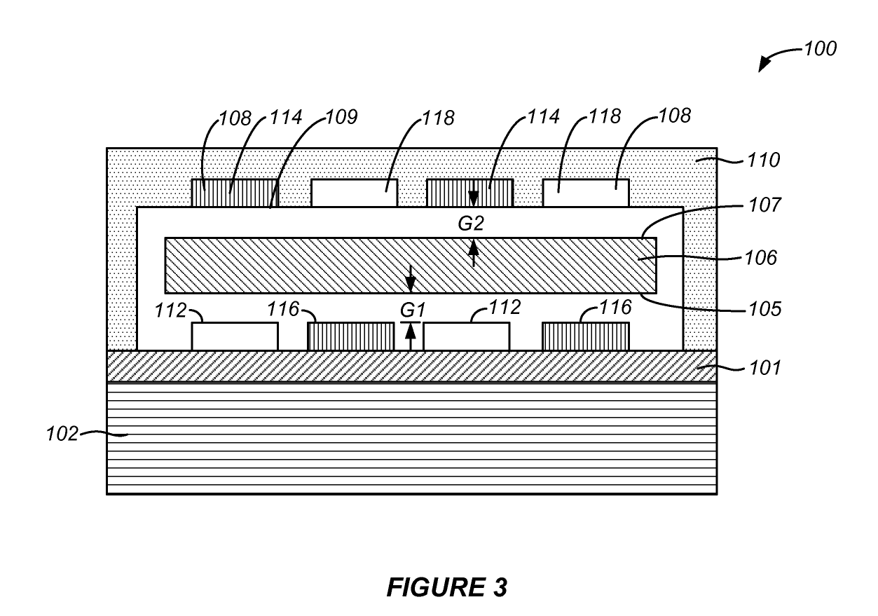

FIG. 3 shows a cross-sectional side view of an example implementation of a piezoelectric resonator structure 100 that includes one or more first electrodes 112, one or more second electrodes 114 arranged opposite the first electrodes 112, one or more third electrodes 116, and one or more fourth electrodes 118 arranged opposite the third electrodes 116. That is, in such implementations, the first conductive layer 104 further includes a third set of one or more third electrodes 116, while the second conductive layer 108 further includes a fourth set of one or more fourth electrodes 118 arranged opposite the third electrodes 116. In some such implementations, the first electrodes 112 are interdigitated with the third electrodes 116, while the second electrodes 114 are interdigitated with the fourth electrodes 118. In some such implementations, the piezoelectric resonator structure 100 depicted in FIG. 3 is configured as a transducer or transformer.

The piezoelectric resonator structure 100 depicted in FIG. 3 also can include a first port 120 (not shown) capable of receiving an input signal, such as a varying input signal, or of being coupled to ground. In some implementations, the first electrodes 112 and third electrodes 116 are coupled to the first port 124. In some such implementations, the first port 120 can be coupled to ground. In some other implementations, the third electrodes 116 are coupled to a third port 124 (not shown). In some of these implementations, the first port 120 can be coupled to a first component of a differential input signal while the third port 124 can output a first component of a differential output signal. The piezoelectric resonator structure 100 depicted in FIG. 3 also can include a second port 122 (not shown) capable of receiving an input signal, such as a varying input signal, and a fourth port 126 (not shown) that can be coupled to a load and capable of outputting an output signal. In some implementations, the second electrodes 114 are coupled to the second port 122, which is coupled to a second component of the differential input signal, and the fourth electrodes 118 are coupled to the fourth output port 126, which can output a second component of the differential output signal.

In some such implementations, a ratio of the number of fourth electrodes 118 to the number of second electrodes 114 characterizes an effective transformation ratio of the piezoelectric resonator structure 100 depicted in FIG. 3. In some implementations, the transformation ratio is related to the impedance ratio of the output impedance measurable at the third and fourth ports 124 and 126 to the input impedance measurable at the first and second ports 120 and 122. For reference, the transformation ratio is a characteristic that is more general than the impedance ratio. Depending on the source impedance or load impedance, the transformation ratio for a signal (voltage or current) may be equal or not to the impedance ratio of the transformer.

Again, in some other implementations, the first and third electrodes 112 and 116 can be a single ground plane. In such implementations, the first port 120 or the third port 124 (if present) can be coupled to ground, the second port 122 (and second electrodes 114) can be coupled to an input signal, and the fourth port 126 (and fourth electrodes 118) can output an output signal.

FIG. 4 shows a cross-sectional side view of an example implementation of a piezoelectric resonator structure 100 that includes one or more first electrodes 112, one or more second electrodes 114 arranged opposite the first electrodes, one or more third electrodes 116, one or more fourth electrodes 118 arranged opposite the third electrodes 116, one or more fifth electrodes 128, and one or more sixth electrodes 130 arranged opposite the fifth electrodes 128. That is, in such implementations, the first conductive layer 104 includes first electrodes 112, third electrodes 116, and fifth electrodes 128 while the second conductive layer 108 can include second electrodes 114, fourth electrodes 118, and sixth electrodes 130 arranged over the first electrodes 112, third electrodes 116, and fifth electrodes 128, respectively. In such an implementation, the piezoelectric resonator structure 100 also can include a first port 120 (not shown), a second port 122 (not shown), a third port 124 (not shown), a fourth port 126 (not shown), a fifth port (not shown), and a sixth port (not shown) to which the first electrodes 112, second electrodes 114, third electrodes 116, fourth electrodes 118, fifth electrodes 128, and sixth electrodes 130 are coupled, respectively. In some implementations, the first port 120 and the fourth port 126 can be coupled to a first component of a differential input signal while the second port 122 and the third port 124 can be coupled to a second component of the differential input signal. In some implementations, the fifth port is arranged to output a first component of a differential output signal while the sixth port is arranged to output a second component of the differential output signal. In some implementations, the piezoelectric resonator structure 100 depicted in FIG. 4 is configured as a transducer or transformer.

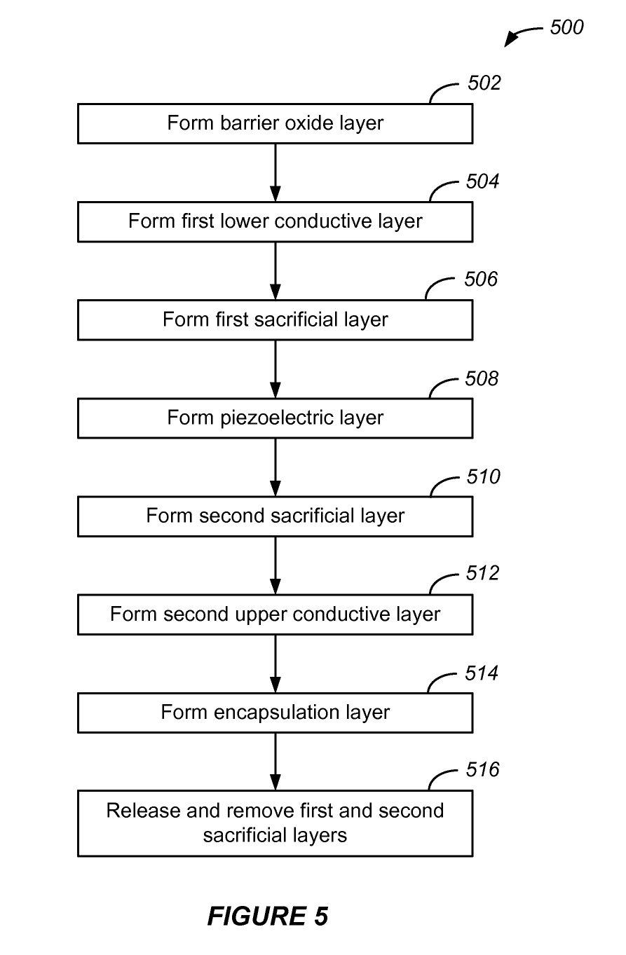

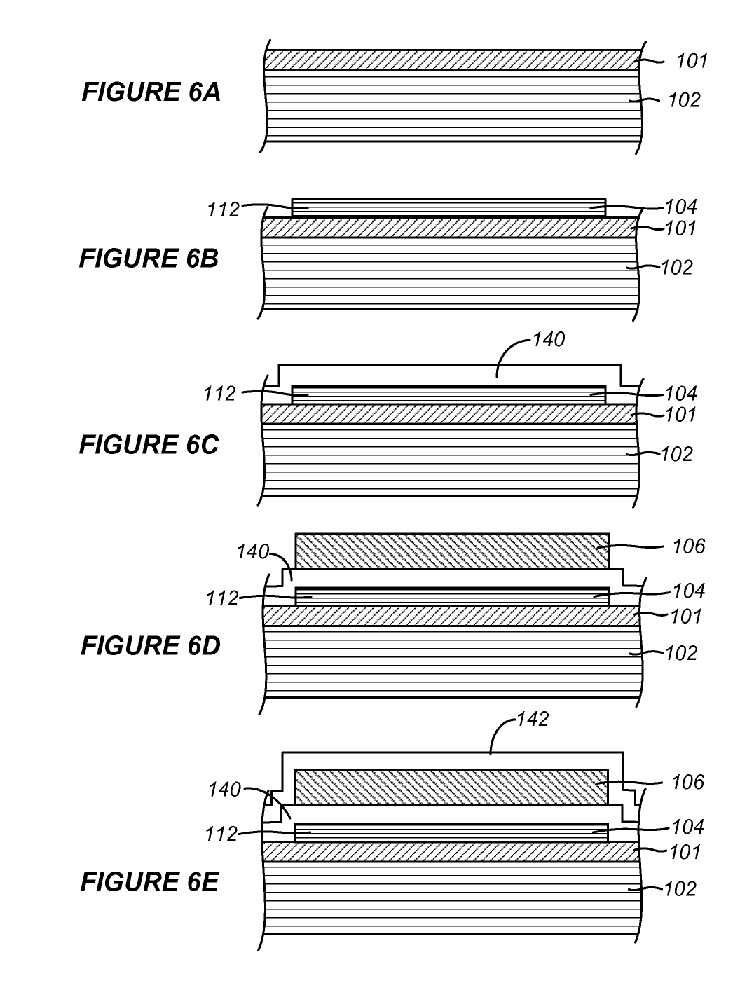

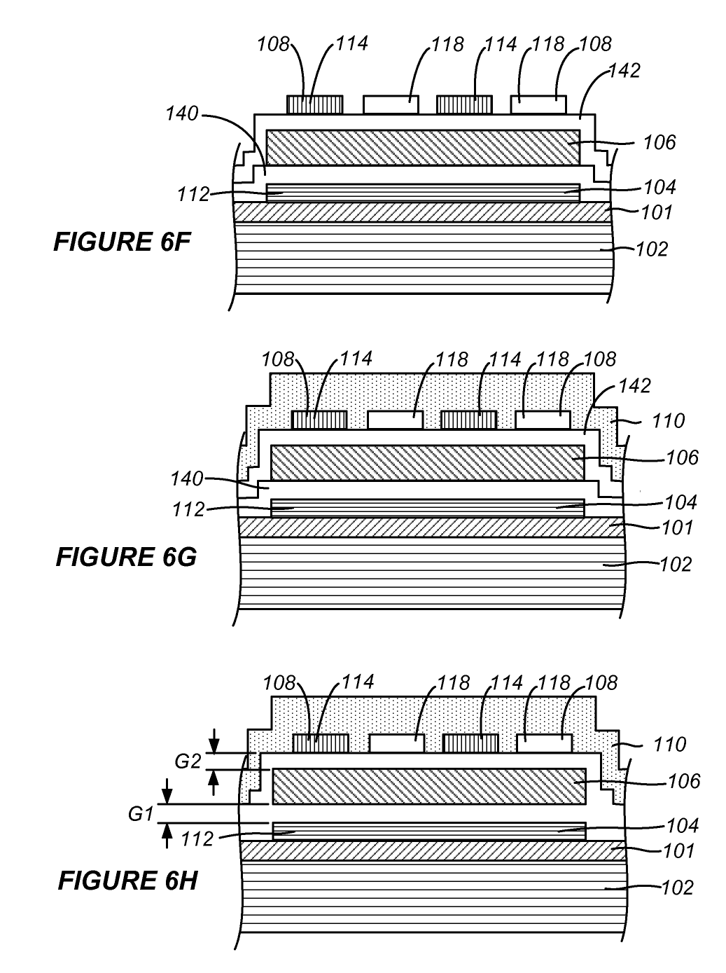

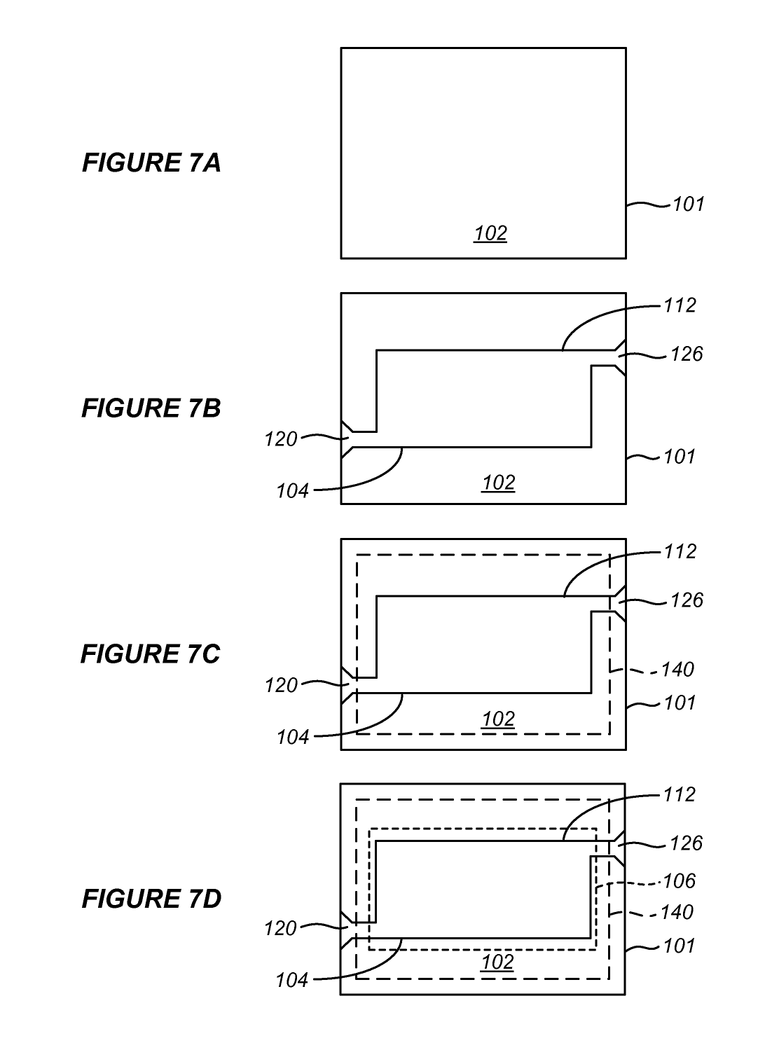

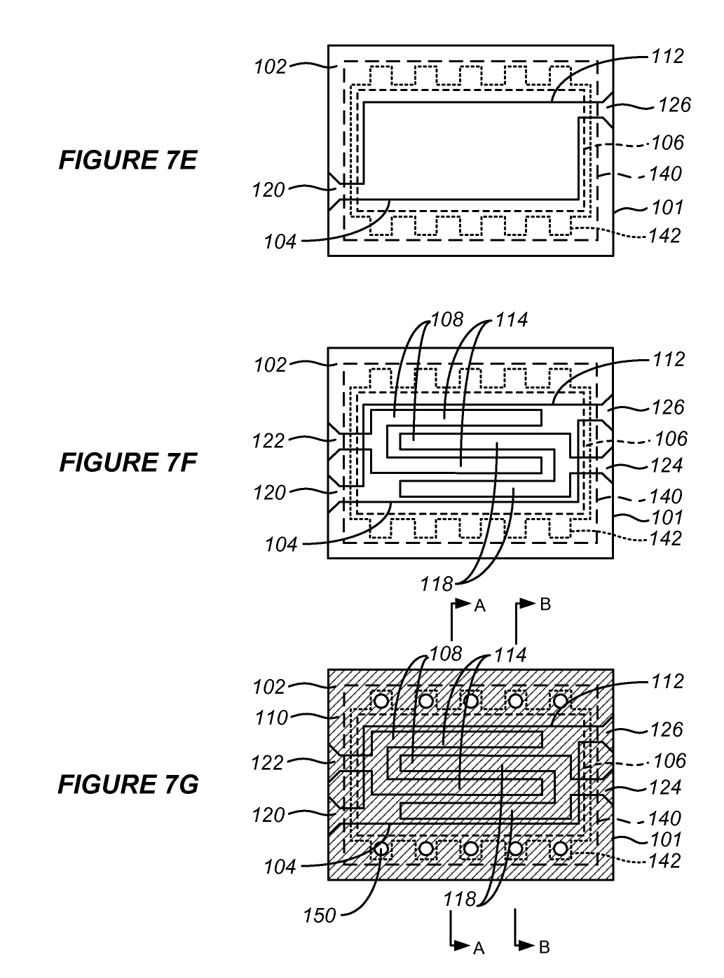

FIG. 5 shows a flow diagram depicting an example process 500 for forming an example piezoelectric resonator structure. For example, the process 500 can be used for producing one or more of the implementations described above with reference to FIGS. 1-4. In some implementations, the process 500 includes a 6-stage masking process. Various stages of process 500 will now be described with reference to the cross-sectional side views and overhead top views depicted in FIGS. 6A-6H and FIGS. 7A-7G. FIGS. 6A-6G show cross-sectional side views during various stages of the process depicted in FIG. 5. FIGS. 7A-7G show top views during various stages of the process depicted in FIG. 5.

In some implementations, the process 500 begins in block 502 with depositing a barrier oxide layer (e.g., layer 101) over a substrate (e.g., substrate 102), as FIGS. 6A and 7A show. In block 504, a first lower conductive layer (e.g., first conductive layer 104) is formed over the barrier oxide layer 101 (or the substrate if the barrier oxide layer is not present), as depicted in FIGS. 6B and 7B. The first conductive layer 104 is made of a conductive material such as metal (examples are described above and below) and can be patterned to define one or more sets of one or more electrodes (e.g., first and third electrodes 112 and 116), depending on the desired configuration. When more than one electrode is defined, the electrodes can be connected at separate ports of the resonator device.

In block 506, a first sacrificial layer 140 is masked and formed over portions of the first conductive layer 104 and the substrate 102 as FIGS. 6C and 7C show. In block 508, a piezoelectric layer (e.g., piezoelectric layer 106) is formed over the first sacrificial layer 140 as FIGS. 6D and 7D show. In block 510, a second sacrificial layer 142 is masked and formed over the piezoelectric layer 106 as FIGS. 6E and 7E show. In block 512, a second conductive layer (e.g., second conductive layer 108) is masked and formed over the second sacrificial layer 142 as FIGS. 6F and 7F show. The second conductive layer 108 is made of a conductive material such as metal (examples are described above below) and can be patterned to define one or more sets of one or more electrodes (e.g., second and fourth electrodes 114 and 118), depending on the desired configuration. When more than one electrode is defined, the electrodes can be connected at separate ports of the resonator device. In block 514, an encapsulation layer (e.g., encapsulation layer 110) is formed over the second conductive layer 108 as FIGS. 6G and 7G show. In some implementations, encapsulation layer 110 is formed such that encapsulation layer 110 includes release holes 150. In some implementations, release holes 150 enable release material to reach sacrificial layers 140 and 142 as described below.

In block 516, the sacrificial layers 140 and 142 are released to define a lower gap G1 separating the piezoelectric layer 106 from the first lower conductive layer 104 and an upper gap G2 separating the piezoelectric layer 106 from the second upper conductive layer 108, as FIG. 6H shows. The encapsulation layer 110 is attached to the otherwise floating or suspended electrodes of the upper conductive layer 108 to support and hold the electrodes of the upper conductive layer in position in close proximity to, but separated from, the piezoelectric layer 106. The sacrificial layers 140 and 142 can be formed of a material such as molybdenum (Mo) or amorphous silicon (a-Si). For instance, a xenon difluoride (XeF₂) gas can be introduced through release holes 150 to release and remove the sacrificial layers 140 and 142. In an alternative implementation, the sacrificial layers 140 and 142 can be formed of SiO₂, and a hydrogen fluoride (HF) gas can be introduced to release and remove the sacrificial layers.

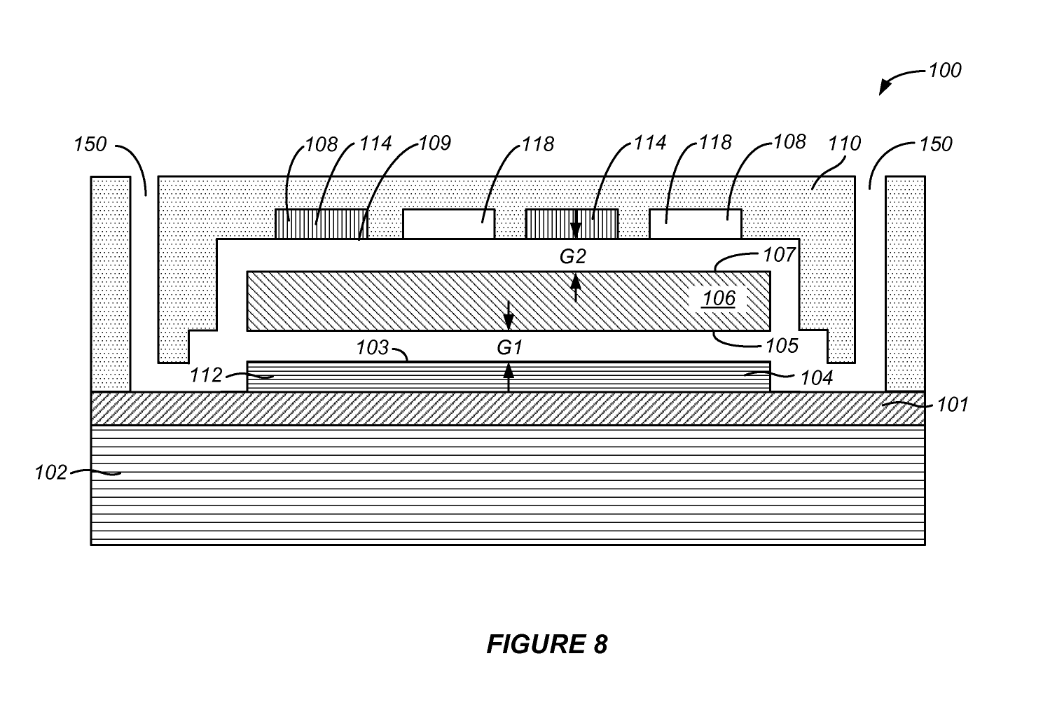

FIG. 8 shows another cross-sectional side view of the example piezoelectric resonator structure 100 depicted in FIG. 1. For example, the cross-sectional side view depicted in FIG. 1 is taken along section A-A depicted in FIG. 7G. The cross-sectional side view depicted in FIG. 8 is taken along section B-B depicted in FIG. 7G to show an example configuration of example release holes 150 for facilitating the release and removal of sacrificial layers 140 and 142.

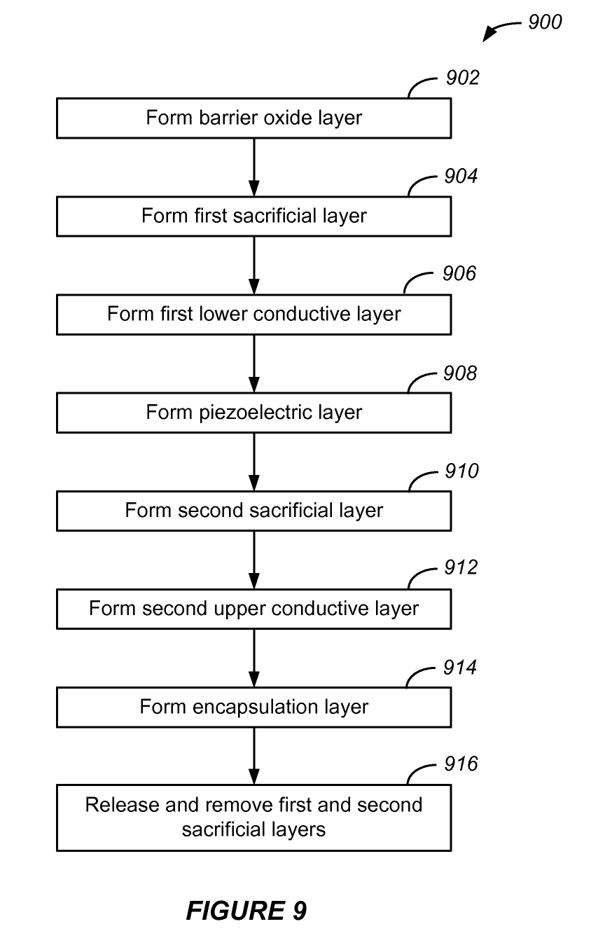

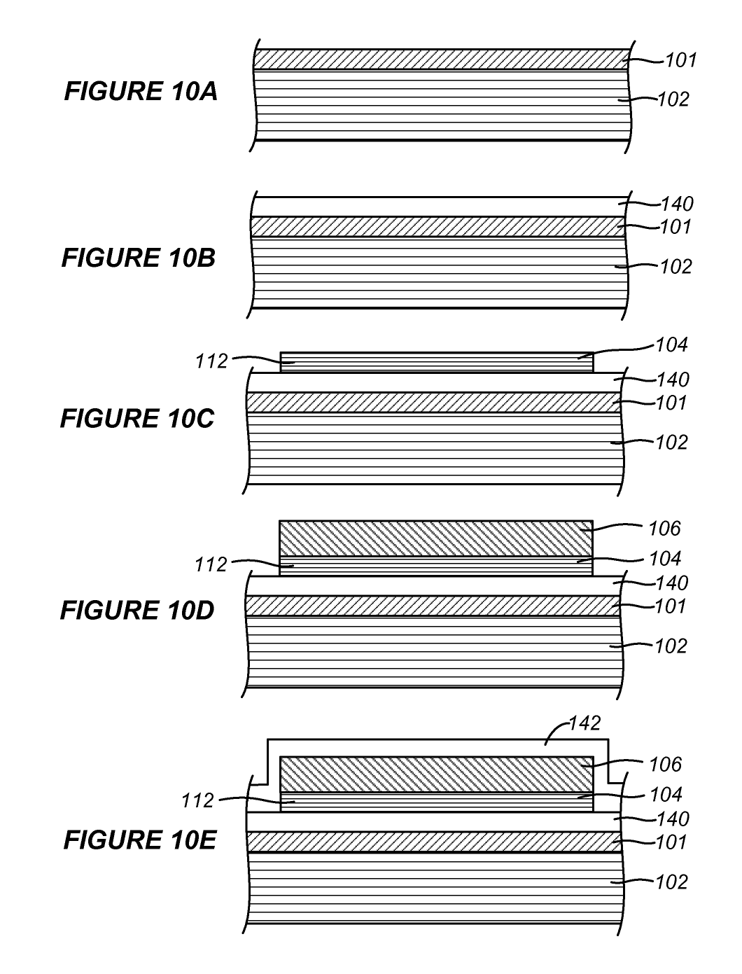

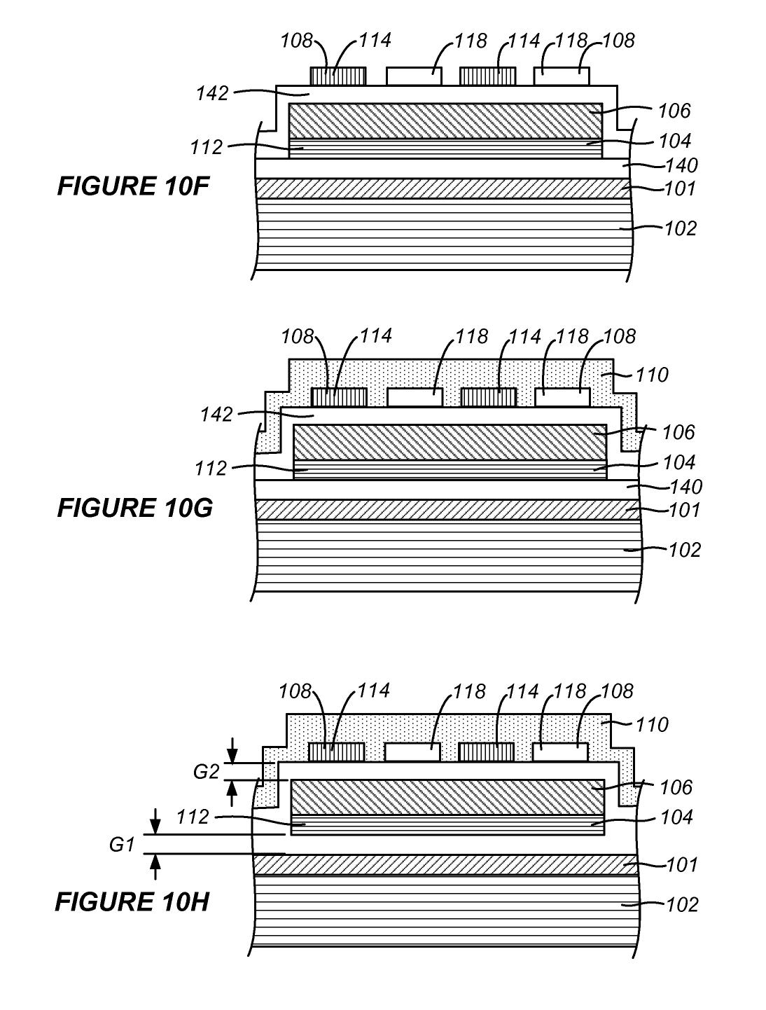

FIG. 9 shows a flow diagram depicting another example process 900 for forming a piezoelectric resonator structure. FIGS. 10A-10H show cross-sectional side views during various stages of the example process 900 depicted in FIG. 9. In some implementations, executing the process 900 results in a piezoelectric resonator structure 100 having an upper gap G2 between the upper conductive layer and the piezoelectric layer. In contrast to the implementation depicted in FIGS. 5-8, the process 900 produces a piezoelectric resonator in which the lower conductive layer is attached to the piezoelectric layer, and in which the lower gap G1 is between the conductive layer and the substrate. In some implementations, the process 900 begins in block 902 with depositing a barrier oxide layer (e.g., layer 101) over a substrate (e.g., substrate 102), as FIG. 10A shows. In block 904, a first sacrificial layer 140 is masked and formed over portions of the barrier oxide layer 101 (or the substrate if the barrier oxide layer is not present) as depicted in FIG. 10B.

In block 906, a first lower conductive layer (e.g., first conductive layer 104) is formed over the first sacrificial layer 140, as FIG. 10C shows. The first conductive layer 104 is made of a conductive material such as metal (examples are described above and below) and can be patterned to define one or more sets of one or more electrodes (e.g., first and third electrodes 112 and 116), depending on the desired configuration. When more than one electrode is defined, the electrodes can be connected at separate ports of the resonator device.

In block 908, a piezoelectric layer (e.g., piezoelectric layer 106) is formed over the first sacrificial layer 140 as FIG. 10D shows. In block 910, a second sacrificial layer 142 is masked and formed over the piezoelectric layer 106 as FIG. 10E shows. In block 912, a second conductive layer (e.g., second conductive layer 108) is masked and formed over the second sacrificial layer 142 as FIG. 10F shows. The second conductive layer 108 is made of a conductive material such as metal (examples are described above below) and can be patterned to define one or more sets of one or more electrodes (e.g., second and fourth electrodes 114 and 118), depending on the desired configuration. When more than one electrode is defined, the electrodes can be connected at separate ports of the resonator device.

In block 914, an encapsulation layer (e.g., encapsulation layer 110) is formed over the second conductive layer 108 as FIG. 10G shows. In some implementations, encapsulation layer 110 is formed such that encapsulation layer 110 includes release holes 150. In some implementations, the release holes 150 enable release material to reach sacrificial layers 140 and 142 as described below.

In block 916, the sacrificial layers 140 and 142 are released to define a lower gap G1 separating the first lower conductive layer 104 from the barrier oxide layer 101, and an upper gap G2 separating the piezoelectric layer 106 from the second upper conductive layer 108, as FIG. 10H shows. The encapsulation layer 110 is attached to the otherwise floating or suspended electrodes of the upper conductive layer 108 to support and hold the electrodes of the upper conductive layer in position in close proximity to, but separated from, the piezoelectric layer 106. The sacrificial layers 140 and 142 can be formed of a material such as Mo or a-Si. For instance, a XeF₂ gas can be introduced through release holes 150 to release and remove the sacrificial layers 140 and 142. In an alternative implementation, the sacrificial layers 140 and 142 can be formed of SiO₂, and a HF gas can be introduced to release and remove the sacrificial layers.

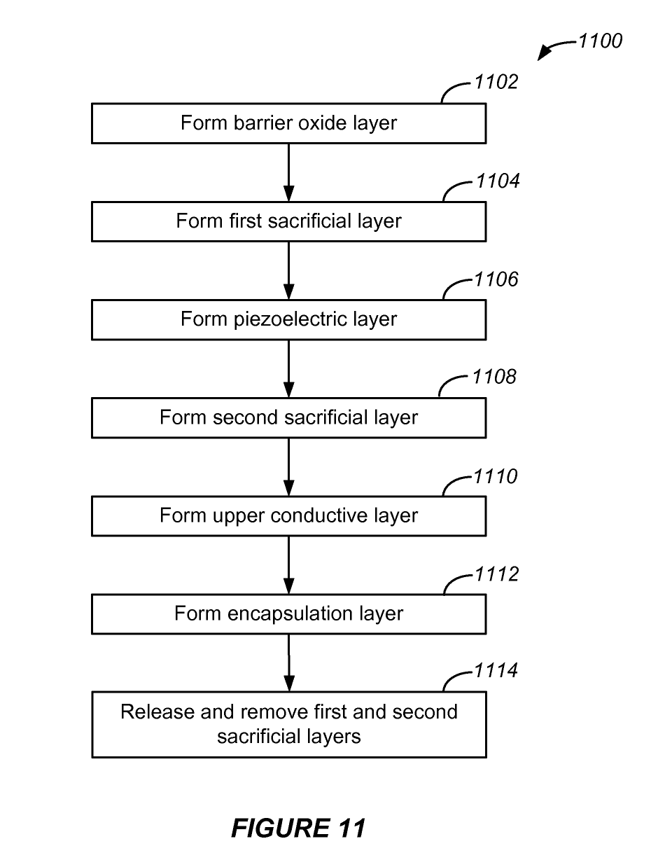

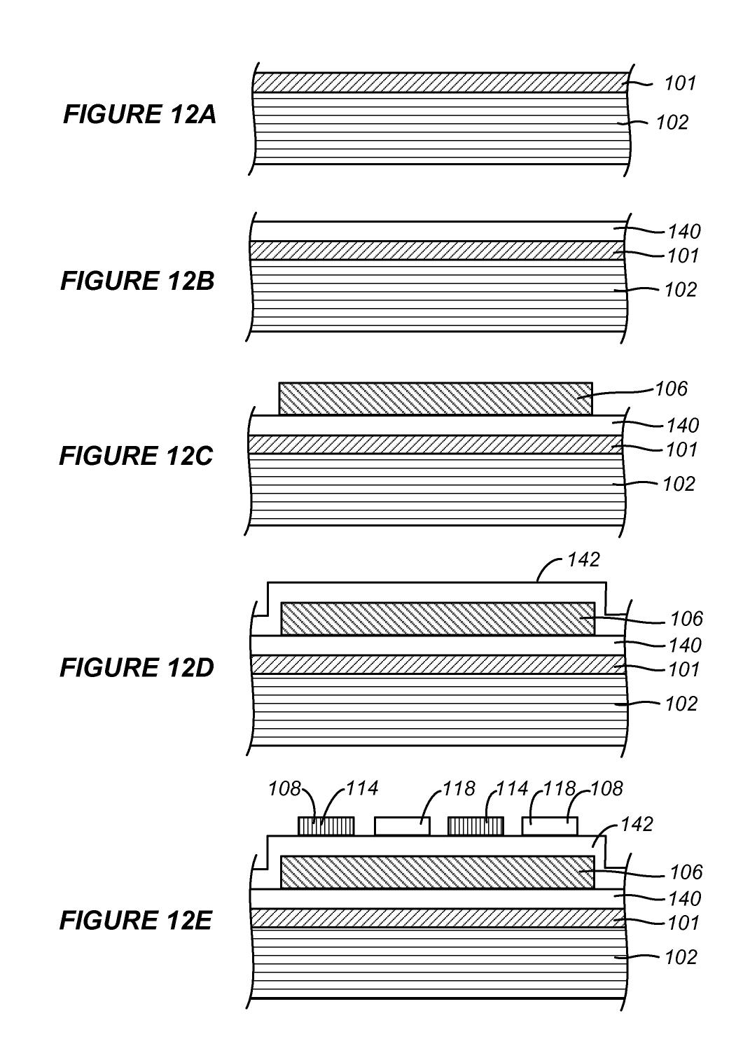

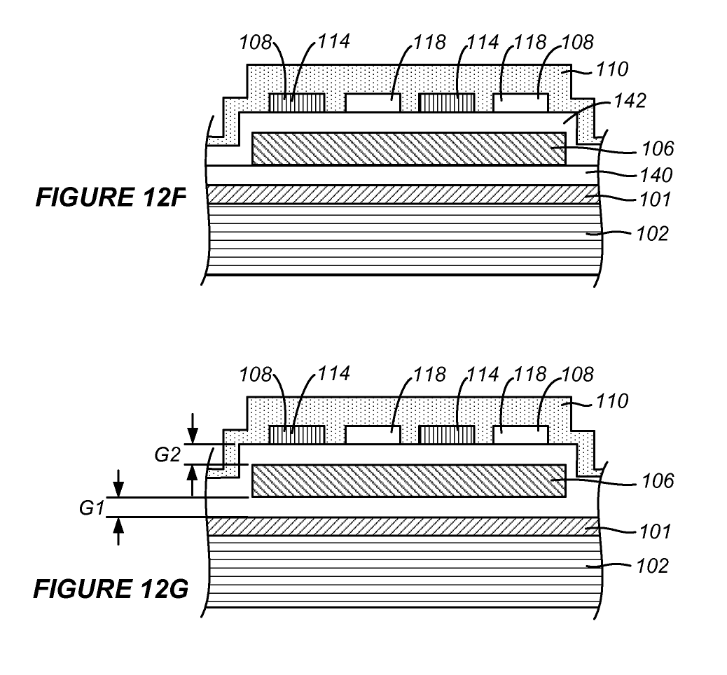

FIG. 11 shows a flow diagram depicting another example process 100 for forming a piezoelectric resonator structure. FIGS. 12A-12G show cross-sectional side views during various stages of the example process 1100 depicted in FIG. 11. In some implementations, executing the process 1100 results in a piezoelectric resonator structure 100 having an upper gap G2 between the upper conductive layer and the piezoelectric layer. In contrast to the implementation depicted in FIGS. 9 and 10A-10H, the process 1100 produce a piezoelectric resonator that does not include a lower conductive layer, and in which the lower gap G1 is between the piezoelectric layer and the substrate. In some implementations, the process 1100 begins in block 1102 with depositing a barrier oxide layer (e.g., layer 101) over a substrate (e.g., substrate 102), as FIG. 12A shows. In block 1104, a first sacrificial layer 140 is masked and formed over portions of the barrier oxide layer 101 (or the substrate if the barrier oxide layer is not present) as FIG. 12B shows.

In block 1106, a piezoelectric layer (e.g., piezoelectric layer 106) is formed over the first sacrificial layer 140 as FIG. 12C shows. In block 1108, a second sacrificial layer 142 is masked and formed over the piezoelectric layer 106 as FIG. 12D shows. In block 1110, a conductive layer (e.g., second conductive layer 108) is masked and formed over the second sacrificial layer 142 as FIG. 12E shows. The conductive layer 108 is made of a conductive material such as metal (examples are described above below) and can be patterned to define one or more sets of one or more electrodes (e.g., second and fourth electrodes 114 and 118), depending on the desired configuration. When more than one electrode is defined, the electrodes can be connected at separate ports of the resonator device.

In block 1112, an encapsulation layer (e.g., encapsulation layer 110) is formed over the conductive layer 108 as FIG. 12F shows. In some implementations, encapsulation layer 110 is formed such that encapsulation layer 110 includes release holes 150. In some implementations, release holes 150 enable release material to reach sacrificial layers 140 and 142 as described below.

In block 1114, the sacrificial layers 140 and 142 are released to define a lower gap G1 separating the piezoelectric layer from the barrier oxide layer 101, and an upper gap G2 separating the piezoelectric layer 106 from the upper conductive layer 108, as FIG. 12G shows. The encapsulation layer 110 is attached to the otherwise floating or suspended electrodes of the conductive layer 108 to support and hold the electrodes of the conductive layer in position in close proximity to, but separated from, the piezoelectric layer 106. The sacrificial layers 140 and 142 can be formed of a material such as Mo or a-Si. For instance, a XeF₂ gas can be introduced through release holes 150 to release and remove the sacrificial layers 140 and 142. In an alternative implementation, the sacrificial layers 140 and 142 can be formed of SiO₂, and a HF gas can be introduced to release and remove the sacrificial layers.

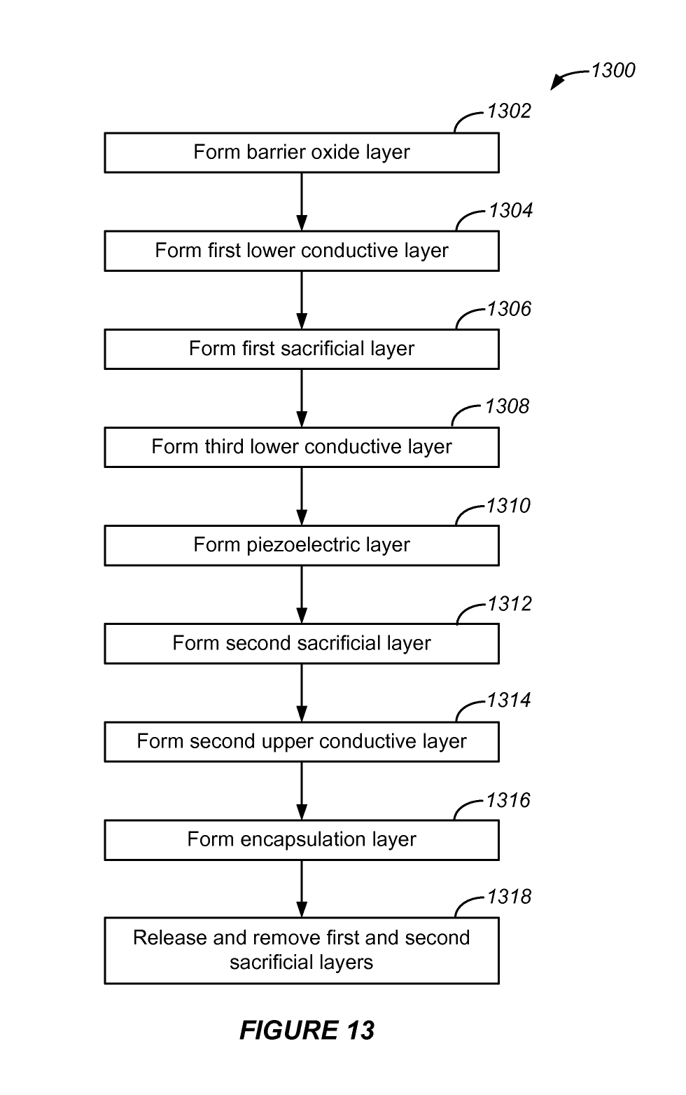

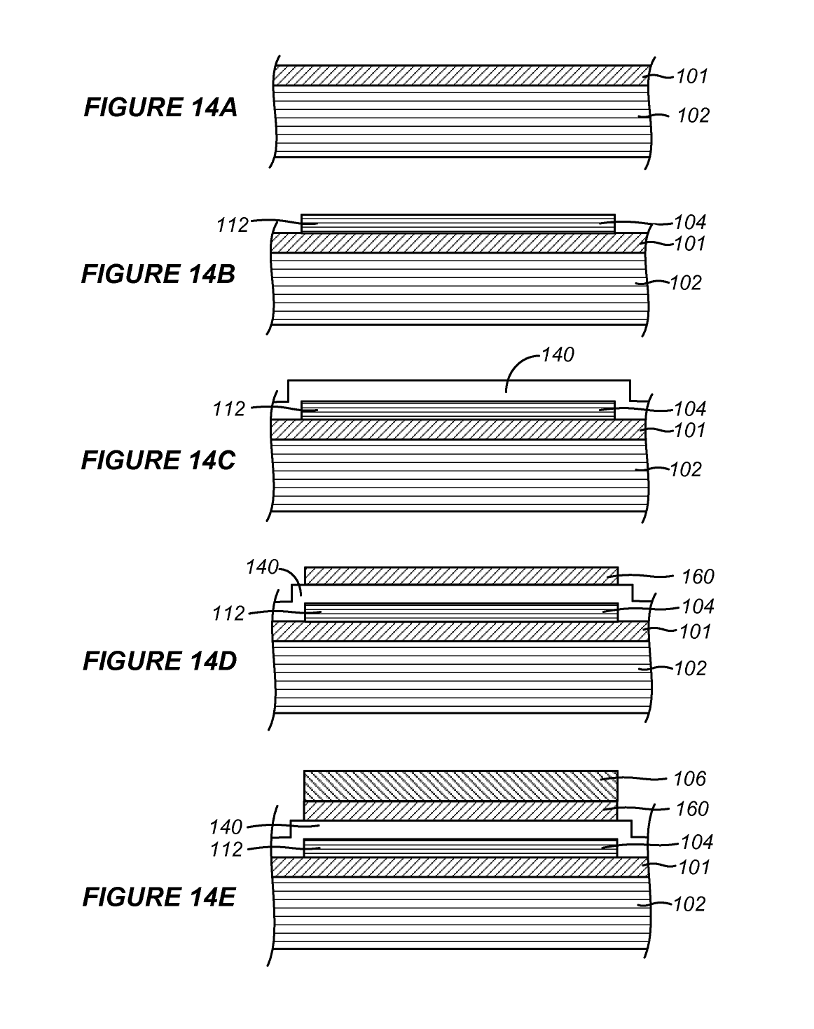

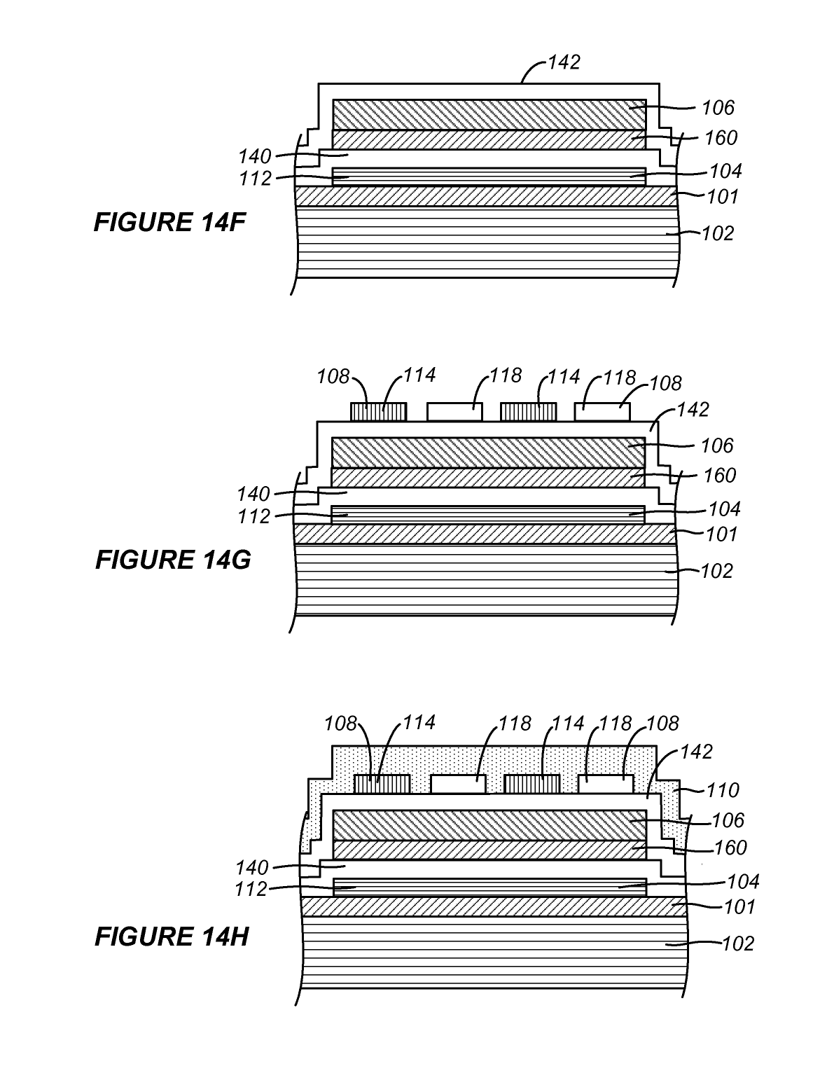

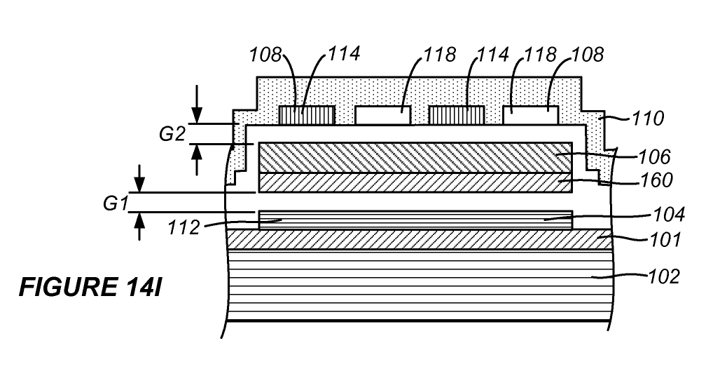

FIG. 13 shows a flow diagram depicting another example process 1300 for forming a piezoelectric resonator structure. FIGS. 14A-14I show cross-sectional side views during various stages of the example process 1300 depicted in FIG. 13. In some implementations, executing the process 1300 results in a piezoelectric resonator structure 100 that further includes a third lower conductive layer attached to the bottom surface of the piezoelectric layer, and in which the lower gap G1 is between the first conductive layer and the third conductive layer. In some implementations, the process 1300 begins in block 1302 with depositing a barrier oxide layer (e.g., layer 101) over a substrate (e.g., substrate 102), as FIG. 14A shows.

In block 1304, a first lower conductive layer (e.g., first conductive layer 104) is formed over the barrier oxide layer 101 (or substrate 102), as FIG. 14B shows. The first conductive layer 104 is made of a conductive material such as metal (examples are described above and below) and can be patterned to define one or more sets of one or more electrodes (e.g., first and third electrodes 112 and 116), depending on the desired configuration. When more than one electrode is defined, the electrodes can be connected at separate ports of the resonator device.

In block 1306, a first sacrificial layer 140 is masked and formed over portions of the barrier oxide layer 101 (or the substrate if the barrier oxide layer is not present) as FIG. 14C shows. In block 1308, a third lower conductive layer 160 is formed over the first sacrificial layer 140, as FIG. 14D shows. The third conductive layer 160 is made of a conductive material such as metal (examples are described above and below) and can be patterned to define one or more sets of one or more electrodes (e.g., overlying first and third electrodes 112 or 116), depending on the desired configuration. When more than one electrode is defined, the electrodes can be connected at separate ports of the resonator device.

In block 1310, a piezoelectric layer (e.g., piezoelectric layer 106) is formed over the third conductive layer 160 as FIG. 14E shows. In block 1312, a second sacrificial layer 142 is masked and formed over the piezoelectric layer 106 as FIG. 14F shows. In block 1314, a second conductive layer (e.g., second conductive layer 108) is masked and formed over the second sacrificial layer 142 as FIG. 14G shows. The second conductive layer 108 is made of a conductive material such as metal (examples are described above below) and can be patterned to define one or more sets of one or more electrodes (e.g., second and fourth electrodes 114 and 118), depending on the desired configuration. When more than one electrode is defined, the electrodes can be connected at separate ports of the resonator device.

In block 1316, an encapsulation layer (e.g., encapsulation layer 110) is formed over the second conductive layer 108 as FIG. 14H shows. In some implementations, encapsulation layer 110 is formed such that encapsulation layer 110 includes release holes 150. In some implementations, the release holes 150 enable release material to reach sacrificial layers 140 and 142 as described below.

In block 1318, the sacrificial layers 140 and 142 are released to define a lower gap G1 separating the first lower conductive layer 104 from the third conductive layer 160, and an upper gap G2 separating the piezoelectric layer 106 from the upper conductive layer 108, as FIG. 14I shows. The encapsulation layer 110 is attached to the otherwise floating or suspended electrodes of the upper conductive layer 108 to support and hold the electrodes of the upper conductive layer in position in close proximity to, but separated from, the piezoelectric layer 106. The sacrificial layers 140 and 142 can be formed of a material such as Mo or a-Si. For instance, a XeF₂ gas can be introduced through release holes 150 to release and remove the sacrificial layers 140 and 142. In an alternative implementation, the sacrificial layers 140 and 142 can be formed of SiO₂, and a HF gas can be introduced to release and remove the sacrificial layers.

In some other implementations, one or more of processes 500, 900, 1100 and 1300 can be combined or performed in parallel. For example, one or more stages of one or more of processes 500, 900, 1100 and 1300 can be combined in the production of a single device such that the device includes one or more of each of the resonator structures produced using the processes 500, 900, 1100 and 1300. For example, stages 514, 914, 1112 and 1316 can be performed in a single stage using appropriate masking.

The piezoelectric materials that also can be used in the fabrication of the piezoelectric layers 106 of electromechanical systems resonators disclosed herein include, for example, AlN, zinc oxide (ZnO), gallium arsenide (GaAs), aluminum gallium arsenide (AlGaAs), gallium nitride (GaN), quartz and other piezoelectric materials such as zinc-sulfide (ZnS), cadmium-sulfide (CdS), lithium tantalite (LiTaO3), lithium niobate (LiNbO3), lead zirconate titanate (PZT), members of the lead lanthanum zirconate titanate (PLZT) family, doped aluminum nitride (AlN:Sc), and combinations thereof.

The first and second conductive layers 104 and 108 also can be formed of Al, Copper (Cu), Titanium (Ti), Aluminum Nitride (AlN), Titanium Nitride (TiN), Aluminum Copper (AlCu), Mo, aluminum silicon (AlSi), Platinum (Pt), Tungsten (W), Ruthenium (Ru), or other appropriate or suitable materials or combinations thereof. In some implementations, as described above, the first and second conductive layers 104 and 108 have a thickness between approximately 4000 Å and approximately 40000 Å depending on the desired implementation. In some cases, one or both of the conductive layers 104 and 108 is deposited as a bi-layer with a metal such as Mo deposited on top of a seed layer such as AlN. An appropriate thickness for the seed layer can be, for example, 100 to 1000 Å.

The piezoelectric resonators described with reference to FIGS. 1-14 include patterns of metal electrodes in the upper and lower conductive layers that, when provided one or more electrical input signals, cause the piezoelectric layers to have a motional response. The motional response can include a vibrational oscillation along one or more of the X, Y and Z axes. The resonant frequency response of the transformers can be controlled according to a periodic arrangement of the electrodes in the conductive layers, for instance, by adjusting the width(s) as well as the spacing(s) of the electrodes from one another in a conductive layer, such as along the X axis as further explained below.

The pattern of interdigitated electrodes of the respective conductive layers can be periodic in one direction, for instance, along the X axis. The periodic arrangement of electrodes includes alternating areas of metal, representing electrode regions, and space regions, i.e., areas without metal. Such space regions between the electrodes are also referred to herein as “spaces.” In various implementations, the areas of metal and the spaces have the same width, the areas of metal are wider than the spaces, the areas of metal are narrower than the spaces, or any other appropriate relation between the metal widths and spaces. The finger width of the resonator, a parameter based on a combination of electrode width and spacing, can be adjusted to control one or more resonant frequencies of the structure. For instance, a first finger width in a conductive layer can correspond to a first resonant frequency, and a second finger width in the conductive layer can provide a different second resonant frequency.

The fundamental frequency for the displacement of the piezoelectric layer can be set in part lithographically by the planar dimensions of the upper electrodes, the lower electrodes, and/or the piezoelectric layer. At the device resonant frequency, the electrical signal across the device is reinforced and the device behaves as an electronic resonant circuit. For instance, the piezoelectric resonator transformers described above can be implemented by patterning the input electrodes and output electrodes of a respective conductive layer symmetrically.

The total width, length, and thickness of the piezoelectric resonator transformer are parameters that also can be designated to optimize performance. In some implementations, the finger width of the resonator is the main parameter that is controlled to adjust the resonant frequency of the structure, while the total width multiplied by the total length of the resonator (total area) can be set to control the impedance of the piezoelectric resonator transformer. In one example, the lateral dimensions, i.e., the total width and length of the piezoelectric resonator transformer can be on the order of several 100 μm by several 100 μm for a device designed to operate around 1 GHz (the finger width can be a few microns for 1 GHz operation in case of AlN as the piezoelectric material). In another example, the lateral dimensions are several 100 μm by several 100 μm for a device designed to operate at around 10 MHz.

The description herein is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the IMOD. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

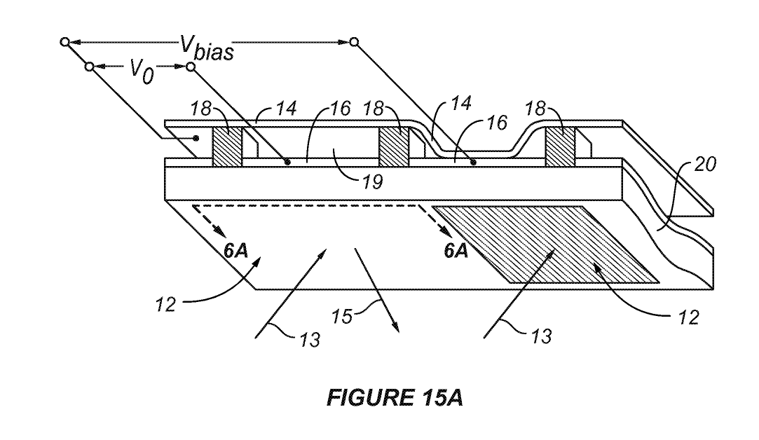

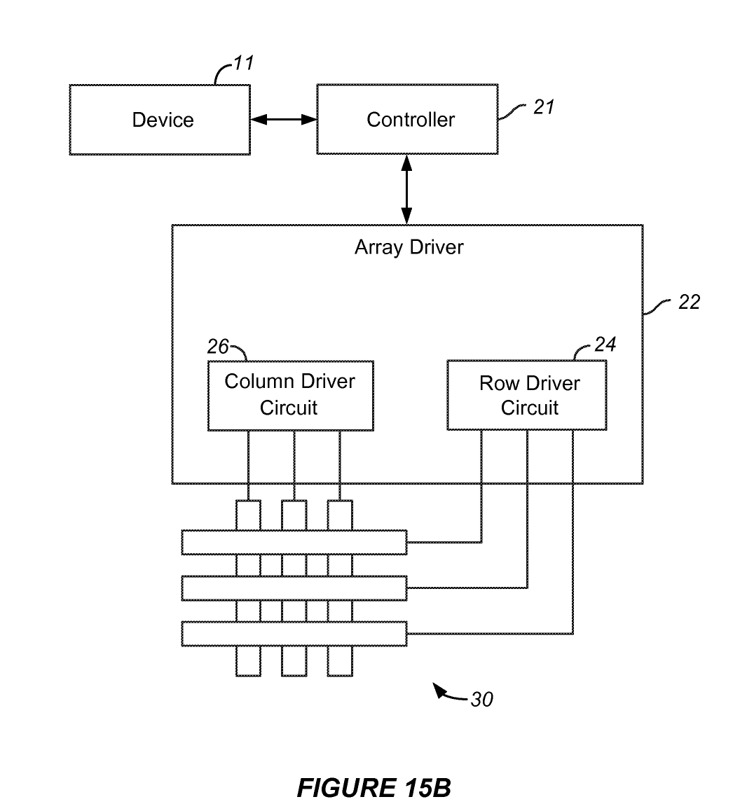

FIG. 15A shows an example of an isometric view depicting two adjacent pixels in a series of pixels of an IMOD display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (such as infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 15A includes two adjacent IMODs 12. In the IMOD 12 on the left (as illustrated), a movable reflective layer 14 is illustrated in a relaxed position at a predetermined distance from an optical stack 16, which includes a partially reflective layer. The voltage V0 applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage Vbias applied across the IMOD 12 on the right is sufficient to maintain the movable reflective layer 14 in the actuated position.

In FIG. 15A, the reflective properties of pixels 12 are generally illustrated with arrows 13 indicating light incident upon the pixels 12, and light 15 reflecting from the IMOD 12 on the left. Although not illustrated in detail, it will be understood by one having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the IMOD 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the separation between posts 18 may be approximately 1-1000 μm, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the IMOD 12 on the left in FIG. 15A, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated IMOD 12 on the right in FIG. 15A. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

FIG. 15B shows an example of a system block diagram depicting an electronic device incorporating a 3×3 IMOD display. The electronic device depicted in FIG. 15B represents one implementation in which a piezoelectric resonator transformer constructed in accordance with the implementations described above with respect to FIGS. 1-10 can be incorporated. The electronic device in which device 11 is incorporated may, for example, form part or all of any of the variety of electrical devices and electromechanical systems devices set forth above, including both display and non-display applications.

Here, the electronic device includes a controller 21, which may include one or more general purpose single- or multi-chip microprocessors such as an ARM®, Pentium®, 8051, MIPS®, Power PC®, or ALPHA®, or special purpose microprocessors such as a digital signal processor, microcontroller, or a programmable gate array. Controller 21 may be configured to execute one or more software modules. In addition to executing an operating system, the controller 21 may be configured to execute one or more software applications, including a web browser, a telephone application, an email program, or any other software application.

The controller 21 is configured to communicate with device 11. The controller 21 also can be configured to communicate with an array driver 22. The array driver 22 can include a row driver circuit 24 and a column driver circuit 26 that provide signals to, e.g., a display array or panel 30. Although FIG. 15B shows a 3×3 array of IMODs for the sake of clarity, the display array 30 may contain a very large number of IMODs, and may have a different number of IMODs in rows than in columns, and vice versa. Controller 21 and array driver 22 may sometimes be referred to herein as being “logic devices” and/or part of a “logic system.”

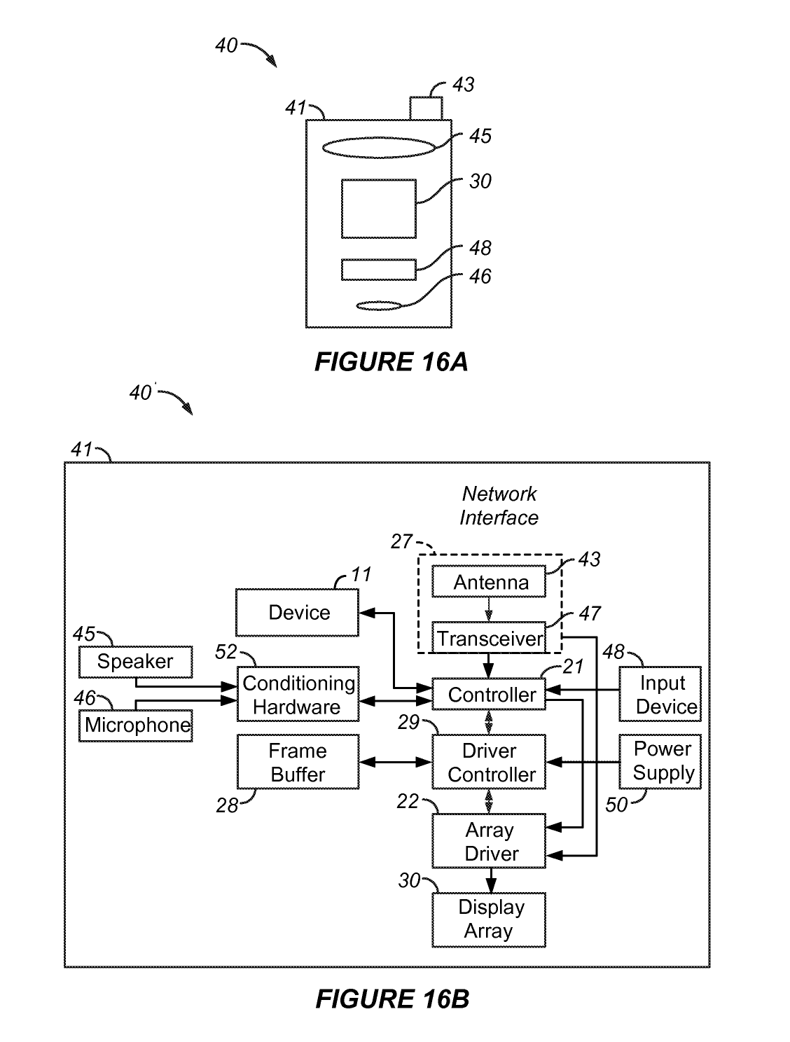

FIGS. 16A and 16B show examples of system block diagrams depicting a display device 40 that includes a plurality of IMODs. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48 and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with the display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A piezoelectric resonator structure comprising:
a first conductive layer including one or more first electrodes;
a second conductive layer including one or more second electrodes;
a piezoelectric layer including one or more layers of piezoelectric material, the piezoelectric layer being arranged between the first conductive layer and the second conductive layer, at least a portion of the surface of the piezoelectric layer adjacent to the first conductive layer being separated from the first conductive layer by a first gap, at least a portion of the surface of the piezoelectric layer adjacent to the second conductive layer being separated from the second conductive layer by a second gap; and
an encapsulation layer arranged over the second conductive layer, the encapsulation layer providing physical support to the second conductive layer;
wherein the first and second conductive layers are configured such that the piezoelectric layer is capable of displacement responsive to one or more electrical signals provided to one or more of the first or second electrodes.

2. The piezoelectric resonator structure of claim 1, wherein one or both of the first and second conductive layers each has a thickness in the range of approximately 4000 Å to approximately 40000 Å.

3. The piezoelectric resonator structure of claim 1, further including a substrate upon which the first conductive layer is formed, the substrate being formed of a dielectric material.

4. The piezoelectric resonator structure of claim 3, further including a barrier oxide layer between the substrate and the first conductive layer.

5. The piezoelectric resonator structure of claim 1, wherein the motional resistance of the structure is less than approximately 1Ω.

6. The piezoelectric resonator structure of claim 1, wherein the piezoelectric layer has a thickness in the range of approximately 4000 Å to approximately 40000 Å.

7. The piezoelectric resonator structure of claim 1, wherein the first gap has a thickness in the range of approximately 10 Å to approximately 1000 Å.

8. The piezoelectric resonator structure of claim 1, wherein the second gap has a thickness in the range of approximately 10 Å to approximately 1000 Å.

9. The piezoelectric resonator structure of claim 1, wherein:
the first conductive layer further includes one or more third electrodes;
the second conductive layer further includes one or more fourth electrodes;
the first electrodes are interdigitated with the third electrodes;
the second electrodes are interdigitated with the fourth electrodes;
the resonator structure further includes a first port capable of receiving an input signal, the second electrodes being coupled to the first port; and
the resonator structure further includes a second port capable of being coupled to a load and capable of outputting an output signal, the fourth electrodes being coupled to the second port.

10. The piezoelectric resonator structure of claim 9, wherein:
the resonator structure further includes one or more third ports coupled to ground; and
the first and the third electrodes are coupled to the one or more third ports.

11. The piezoelectric resonator structure of claim 1, further comprising:
a display;
a processor configured to communicate with the display, the processor being configured to process image data; and
a memory device configured to communicate with the processor.

12. The piezoelectric resonator structure of claim 11, further comprising:
a driver circuit configured to send at least one signal to the display; and
a controller configured to send at least a portion of the image data to the driver circuit.

13. The piezoelectric resonator structure of claim 12, wherein one or more of the electrodes are coupled to send the image data to the processor.

14. A method comprising:
forming a first conductive layer over a substrate, the first conductive layer including one or more first electrodes;
forming a first sacrificial layer over the first conductive layer;
forming a piezoelectric layer over the first sacrificial layer;
forming a second sacrificial layer over the piezoelectric layer;
forming a second conductive layer over the second sacrificial layer, the second conductive layer including one or more second electrodes;
forming an encapsulation layer over the second conductive layer; and
releasing or removing the first and second sacrificial layers to provide:
a first gap between the first conductive layer and the piezoelectric layer such that at least a portion of the surface of the piezoelectric layer adjacent to the first conductive layer is separated from the first conductive layer by the first gap, and
a second gap between the second conductive layer and the piezoelectric layer such that at least a portion of the surface of the piezoelectric layer adjacent to the second conductive layer is separated from the second conductive layer by the second gap;
wherein the encapsulation layer provides physical support to the second conductive layer.

15. The method of claim 14, wherein one or both of the first and second sacrificial layers are formed of molybdenum (Mo) or an amorphous silicon (a-Si) structure.

16. The method of claim 14, wherein one or both of the first and second conductive layers each has a thickness in the range of approximately 4000 Å to approximately 40000 Å.

17. The method of claim 14, wherein the piezoelectric layer has a thickness in the range of approximately 4000 Å to approximately 40000 Å.

18. The method of claim 14, wherein the first gap has a thickness in the range of approximately 10 Å to approximately 1000 Å.

19. The method of claim 14, wherein the second gap has a thickness in the range of approximately 10 Å to approximately 1000 Å.

20. A piezoelectric resonator structure comprising:
first conductive means including one or more first electrodes;
second conductive means including one or more second electrodes;
piezoelectric means including one or more layers of piezoelectric material, the piezoelectric means being arranged between the first conductive means and the second conductive means, at least a portion of the surface of the piezoelectric means adjacent to the first conductive means being separated from the first conductive means by a first gap, at least a portion of the surface of the piezoelectric means adjacent to the second conductive means being separated from the second conductive means by a second gap; and
support means arranged over the second conductive means, the support means providing physical support to the second conductive means;
wherein the first and second conductive means are configured such that the piezoelectric means are capable of displacement responsive to one or more electrical signals provided to one or more of the first or second electrodes.

21. The piezoelectric resonator structure of claim 20, wherein one or both of the first and second conductive layers each has a thickness in the range of approximately 4000 Å to approximately 40000 Å.

22. The piezoelectric resonator structure of claim 20, wherein the piezoelectric layer has a thickness in the range of approximately 4000 Å to approximately 40000 Å.

23. The piezoelectric resonator structure of claim 20, wherein the first gap has a thickness in the range of approximately 10 Å to approximately 1000 Å.

24. The piezoelectric resonator structure of claim 22, wherein the second gap has a thickness in the range of approximately 10 Å to approximately 1000 Å.
